(19) United States
(12) Patent Application Publication
(10) Pub. No.: US 2022/0371901 A1
(43) Pub. Date: Nov. 24, 2022

(54) Methods for Preparing Silicon Carbide Powder and Single Crystal Silicon Carbide

(71) Applicant: Hana Materials Inc., Chungcheongnam-do (KR)

(72) Inventors: In Seok Yang, Gyeonggi-do (KR); Yong Jin Kwon, Gyeongsangnam-do (KR); Il Gon Kim, Chungcheongnam-do (KR)

(21) Appl. No.: 17/770,505

(22) PCT Filed: Oct. 23, 2020
(86) PCT No.: PCT/KR2020/014601

§ 371 Date: Apr. 20, 2022

(30) Foreign Application Priority Data
Oct. 24, 2019 (KR) 10-2019-0133214

(51) Int. Cl. C01B 32/963; C30B 29/36; C30B 23/02

(52) U.S. Cl. CPC C01B 32/963; C30B 29/36; C30B 23/02; C01P 2004/60

(57) ABSTRACT

The present invention relates to methods for preparing silicon carbide powder and single crystal silicon carbide and, more particularly, to a method for preparing silicon carbide powder including: providing a precursor gas onto a fibrous carbon body in a reactor to deposit silicon carbide (SiC) on the fibrous carbon body; recovering the silicon carbide deposited on the fibrous carbon body to obtain a first silicon carbide powder; and oxidizing the first silicon carbide powder, wherein a molecule of the precursor gas include a silicon atom and a carbon atom.

### TECHNICAL FIELD

The present invention relates to methods for preparing silicon carbide powder and single crystal silicon carbide.

### BACKGROUND ART

Recently, rapid technological advances are taking place in the field of semiconductors. Up until now, silicon single crystal has predominantly served as a typical semiconductor device material. However, as the silicon single crystal fails to satisfy the physical properties required in the area of recent semiconductor technologies and has come to a dead end, there is a rising demand for next-generation semiconductor materials that may replace the silicon single crystal.

In particular, semiconductor materials that may significantly reduce power loss upon power conversion are at the center of attention. Among them, silicon carbide (SiC) single crystal having a large bandgap energy (˜3.2 eV) as well as characteristics of smaller size due to high dielectric breakdown, low power loss, and high temperature stability is being highlighted as a promising next-generation semiconductor material.

To make sure that silicon carbide single crystal grows, silicon carbide powder having high purity is indispensable. However, the currently available silicon carbide powder has some limitations such as low purity, an inadequate particle size for use in single crystal growth processes even with high purity, or poor productivity. As the demand for silicon carbide single crystal surges, a process for preparing silicon carbide powder having high purity is also needed.

### DISCLOSURE OF THE INVENTION

### Technical Problem

A task to be solved by the present invention is to provide a method for preparing silicon carbide powder having high purity. Another task to be solved by the present invention is to provide a method for preparing single crystal silicon carbide, using the silicon carbide powder.

### Technical Solution

A method for preparing silicon carbide powder according to the concept of the present invention may include: providing a precursor gas onto a fibrous carbon body in a reactor to deposit silicon carbide (SiC) on the fibrous carbon body; recovering the silicon carbide deposited on the fibrous carbon body to obtain a first silicon carbide powder; and oxidizing the first silicon carbide powder, wherein the molecules of the precursor gas may include silicon atoms and carbon atoms.

A method for preparing single crystal silicon carbide according to another concept of the present invention may include: providing a precursor gas onto a fibrous carbon body in a reactor to deposit silicon carbide on the fibrous carbon body; recovering the silicon carbide deposited on the fibrous carbon body to obtain a first silicon carbide powder; providing a silicon carbide raw material including the first silicon carbide powder into a crucible; and sublimating the silicon carbide raw material to grow single crystal silicon carbide on a seed attached to an upper portion of the crucible.

### Advantageous Effects

The present invention provides a method for preparing silicon carbide powder having high purity. The present invention also provides a method for preparing single crystal silicon carbide having increased purity and yield by using the silicon carbide powder. However, the benefits of the present invention are not limited thereto.

### BRIEF DESCRIPTION OF THE DRAWING

FIG. 1 is a flowchart showing a method for preparing silicon carbide powder according to embodiments of the present invention;

FIGS. 2A and 2B are cross-sectional views describing a method for preparing silicon carbide powder according to embodiments of the present invention:

FIGS. 3A and 3B are enlarged views showing a fibrous carbon body and a fiber bundle from FIGS. 2A and 2B, respectively:

FIG. 4 is an image showing the crystal structure of silicon carbide powder prepared according to embodiments of the present invention;

FIG. 5 is a flowchart showing a method for preparing single crystal silicon carbide according to embodiments of the present invention; and

FIGS. 6A to 6C are cross-sectional views describing a method for preparing single crystal silicon carbide according to embodiments of the present invention.

### MODE FOR CARRYING OUT THE INVENTION

Preferred embodiments of the present invention will be described with reference to the accompanying drawings so as to sufficiently understand constitutions and effects of the present invention. However, the present invention may be embodied in different forms with various changes, but not limited to the embodiments set forth herein. Rather, these embodiments are provided so that this disclosure will be thorough and complete, and will fully convey the scope of the present invention to a person skilled in the art to which the invention pertains.

In this specification, it will be understood that when a component is referred to as being ‘on’ another component, it can be directly on another component, or an intervening third component may also be present. Also, in the drawings, the thicknesses of the components are exaggerated for effectively describing the technical features. Like reference numerals refer to like elements throughout.

Although terms like a first, a second, and a third are used to describe various components in various embodiments of this specification, the components should not be limited to these terms. These terms are used only to tell one element from another element. Embodiments described and exemplified herein include complementary embodiments thereof.

In this specification, the terms are used only for explaining embodiments while not limiting the present invention. In this specification, the singular forms include the plural forms as well, unless the context clearly indicates otherwise. The meaning of “comprises” and/or “comprising” used herein does not exclude the presence or addition of one or more other components besides a mentioned component.

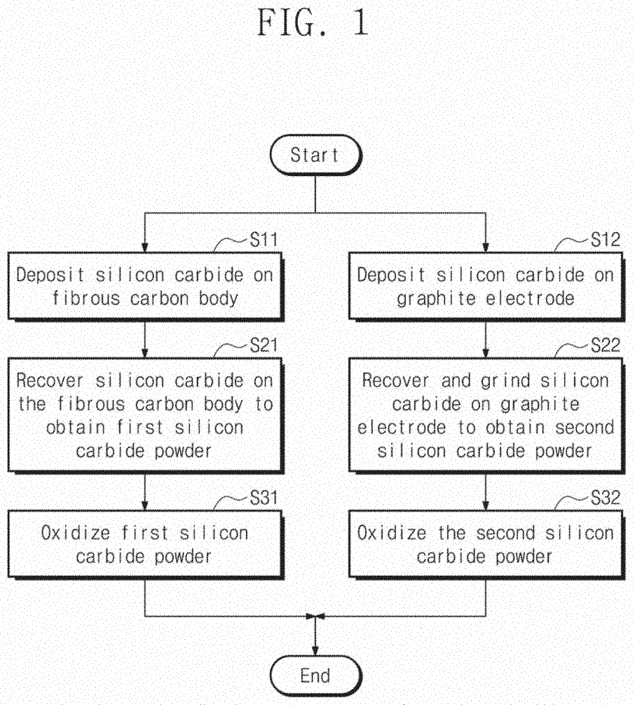

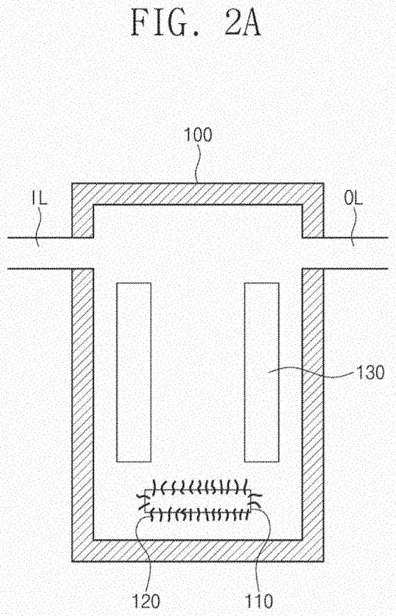

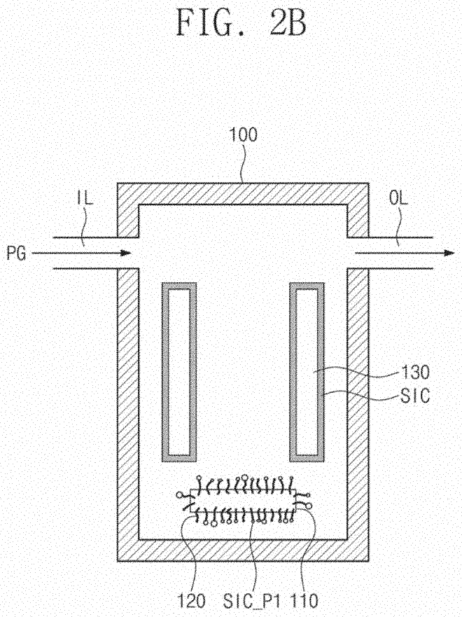

FIG. 1 is a flowchart showing a method for preparing silicon carbide powder according to embodiments of the present invention. FIGS. 2A and 2B are cross-sectional views describing a method for preparing silicon carbide powder according to embodiments of the present invention.

Referring to FIGS. 1, 2A and 2B, a reactor 100 may be provided to prepare silicon carbide powder. The reactor 100 may have a body that includes a material having a high melting point to make sure that a high-temperature thermal process in which silicon carbide is deposited is performed. The body of the reactor 100 may include a metal or an inorganic material, and may include, for example, graphite.

The reactor 100 may include an inlet IL for injecting a precursor gas PG and an outlet OL for discharging the gas after reaction. The placement of the inlet IL and the outlet OL in the reactor 100 is not particularly limited, and, for example, as shown in FIG. 2A, the inlet IL and the outlet OL may be placed apart on the sidewalls of the reactor 100.

As the precursor gas PG, any compound containing at least one silicon atom and at least one carbon atom may be used without particular limitation. The precursor gas PG may include a compound containing at least one silicon atom and at least one carbon atom in a molecule, and may include, for example, methyltrichlorosilane (MTS). As methyltrichlorosilane herein contains silicon atoms and carbon atoms in molecules in a ratio of 1:1, the use of methyltrichlorosilane may increase yield of silicon carbide powder.

The precursor gas may be injected into the reactor 100 through the inlet IL, and deposited on a fibrous carbon body 110 in the reactor 100. A first silicon carbide powder SIC_P1 may be obtained after recovering the silicon carbide.

As the fibrous carbon body 110, any compound containing carbon may be used without any particular limitation, and therefore, activated carbon, carbon fiber, graphite fiber, or a mixture thereof may be used. For example, the fibrous carbon body 110 may include graphite fibers. The fibrous carbon body 110 may be in the form in which several graphite fibers are entangled with each other, and may include a fiber bundle 120 protruding from a surface of the fibrous carbon body. The protruding fiber bundle 120 increases surface areas on which the precursor gas PG may be deposited, and may thus increase the yield of the first silicon carbide powder SIC_P1.

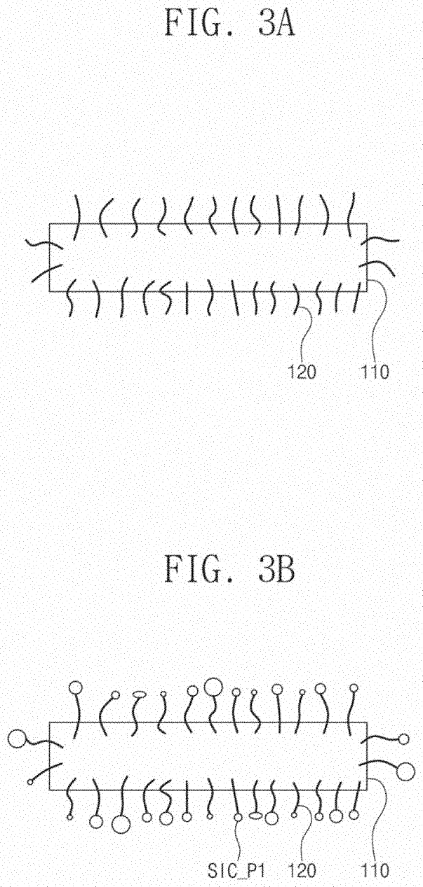

FIGS. 3A and 3B are enlarged views showing the fibrous carbon body 110 and the fiber bundle of FIGS. 2A and 2B, respectively. Referring to FIG. 3B, the first silicon carbide powder SIC_P1 may be deposited in the form of droplets on one end of the fiber bundle 120. For example, the first silicon carbide powder SIC_P1 may have an average particle size of 200 μm to 5 mm.

Referring back to FIGS. 2A and 2B, the reactor 100 may include a graphite electrode 130. The graphite electrode 130 may serve as a heater to heat the inside of the reactor 100. When a voltage is applied to the graphite electrode 130 so that current flows, the graphite electrode 130 may be heated through resistance heating. The heated graphite electrode 130 may increase the temperature inside the reactor 100. For example, when silicon carbide is deposited, the inside of the reactor may be heated at temperatures of 1.400° C. to 1,600° C. When the temperature inside the reactor is less than 1,400° C., the depositing of silicon carbide powder on the fibrous carbon body 110 may not be achieved well, and when the temperature is greater than 1,600° C., silicon carbide powder may have lower quality.

As shown in FIG. 2B, silicon carbide SIC may be deposited on a surface of the graphite electrode 130. The silicon carbide SIC may be conformally formed on the surface of the graphite electrode 130. The silicon carbide SIC deposited on the surface of the graphite electrode 130 may be recovered and ground to obtain a second silicon carbide powder SIC_P2. The second silicon carbide powder SIC_P2 may have a greater average particle size than the first silicon carbide powder SIC_P1, and may have an average particle size of, for example, 200 μm to 10 mm.

The method for preparing silicon carbide powder according to an embodiment of the present invention may include oxidizing the first silicon carbide powder SIC_P1 and the second silicon carbide powder SIC_P2. When the first silicon carbide powder SIC_P1 and the second silicon carbide powder SIC_P2 are oxidized, the yield and productivity of single crystal silicon carbide preparation process may increase.

The method for preparing silicon carbide powder according to an embodiment of the present invention may further include heat-treating silicon carbide powder. When the process of heat-treating is additionally performed, impurities remaining in the silicon carbide powder may be removed to increase purity. For example, the heat-treating of silicon carbide powder may be performed in air at temperatures of 700° C. to 800° C.

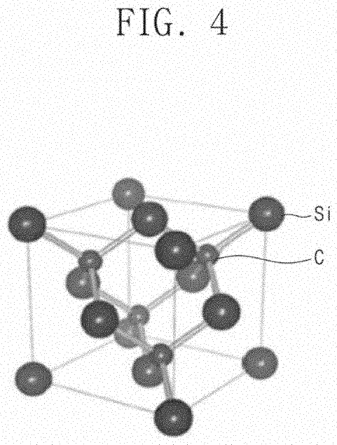

FIG. 4 is an image showing the crystal structures of the first silicon carbide powder SIC_P1 and the second silicon carbide powder SIC_P2 prepared according to the method for preparing the silicon carbide powder of the present invention. As shown in FIG. 4, the first silicon carbide powder SIC_P1 and the second silicon carbide powder SIC_P2 are deposited at temperatures of 1,400° C. to 1,600° C., and may thus have a beta (p) phase crystal structure.

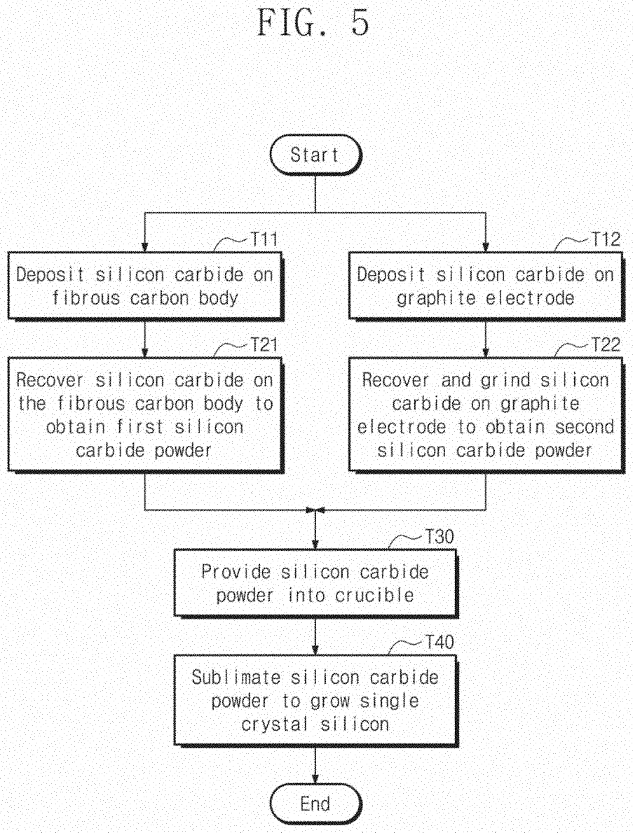

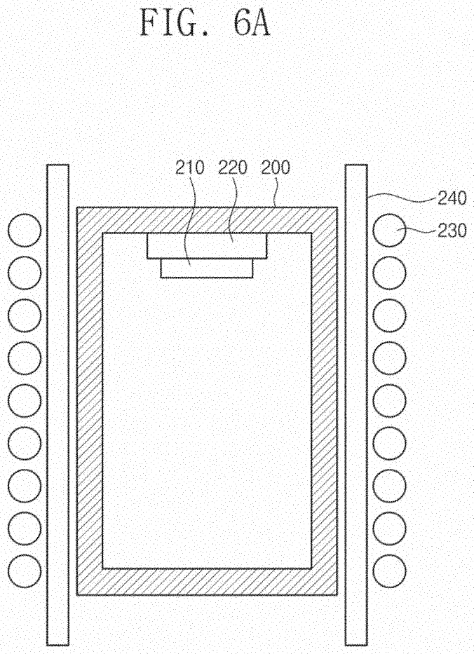

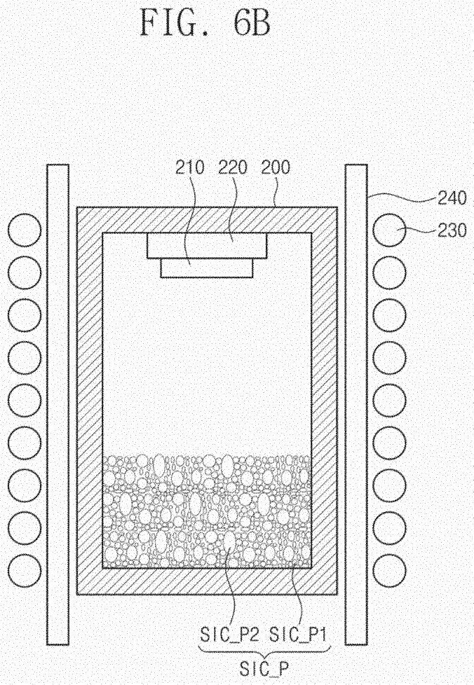

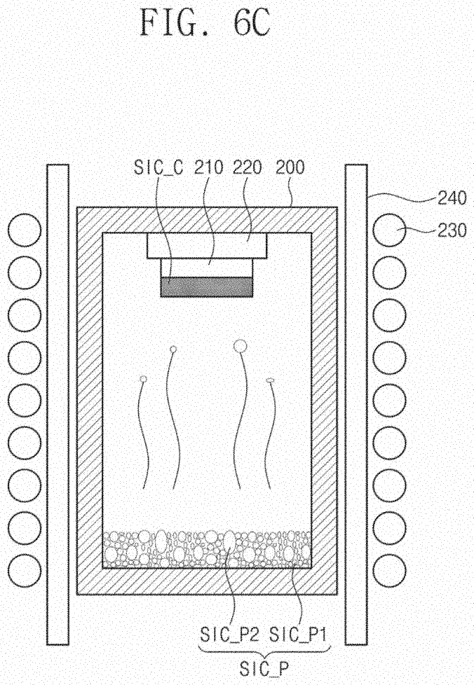

FIG. 5 is a flowchart showing a method for preparing single crystal silicon carbide according to embodiments of the present invention. FIGS. 6A to 6C are cross-sectional views describing a method for preparing single crystal silicon carbide according to embodiments of the present invention.

Referring to FIGS. 5 and 6A to 6C, a crucible 200 may be provided to prepare single crystal silicon carbide SIC_C. Inside the crucible 200, a seed 210 for growing the single crystal silicon carbide SIC_C and a seed holder 220 for fixing the seed 210 onto an upper portion of the crucible 200 may be provided. An induction coil 230 and a reaction chamber 240 may be provided outside the crucible 200.

The crucible 200 may include a body that includes a material having a melting point greater than or equal to the sublimation temperature of silicon carbide. The body of the crucible 200 may include a metal or an inorganic material, and may include, for example, graphite. For example, a material having a melting point greater than or equal to the sublimation temperature of silicon carbide may be applied on a surface of the crucible 200 made of graphite. As a material applied on the surface of the crucible 200, a material that is chemically inert to silicon (Si) at a temperature where the single crystal silicon carbide SIC_C is grown may be used. A material applied on the surface of the crucible 200 may be a metal carbide or a metal nitride, and for example, carbide or nitride of tungsten (W), zirconium (Zr,) tantalum (Ta), hafnium (Hf), or niobium (Nb) may be used.

The seed 210 may provide a surface on which the sublimated silicon carbide raw material may be deposited and grown. The seed holder 220 may be attached to an inner upper side of the crucible 200 in the form that the seed 210 is attached. For example, the seed holder 220 may include high-density graphite, and may be provided with a wider cross-section than the seed 210 to make sure that the seed 210 is stably fixed onto the upper portion of the crucible. For example, as the seed 210, a 4H-SiC seed or a 6H-SiC seed may be used.

As a raw material for growing the single crystal silicon carbide SIC_C, the silicon carbide raw material SIC_P may be provided into the crucible 200. For example, the silicon carbide raw material SIC_P may include the first silicon carbide powder SIC_P1, the second silicon carbide powder SIC_P2, or a mixture thereof prepared through the method for preparing silicon carbide powder, which described above. Detailed descriptions of the first silicon carbide powder SIC_P1 and the second silicon carbide powder SIC_P2 may be substantially the same as what is previously described with reference to FIGS. 2A and 2B.

When the silicon carbide raw material SIC_P includes a mixture of the first silicon carbide powder SIC_P1 and the second silicon carbide powder SIC_P2, the use of the raw material in which silicon carbide powders having different average particle sizes are mixed may control the growth rate of the single crystal silicon carbide SIC_C. For example, when the weight of the first silicon carbide powder SIC_P1 having a relatively small average particle size is greater than the weight of the second silicon carbide powder SIC_P2 having a relatively large average particle size, the growth rate of the single crystal silicon carbide SIC_C may increase. When the weight of the first silicon carbide powder SIC_P1 having a relatively small average particle size is smaller than the weight of the second silicon carbide powder SIC_P2 having a relatively large average particle size, the growth rate of the single crystal silicon carbide SIC_C may decrease. As described above, when adjusting the mixing ratio (weight ratio) between the first silicon carbide powder SIC_P1 and the second silicon carbide powder SIC_P2, the growth rate of the single crystal silicon carbide SIC_C may be controlled to a desired value.

Upon the sublimation of the silicon carbide raw material SIC_P, the temperature inside the crucible may be 1,800° C. to 2,400° C. The inside of the crucible 200 may be heated through the induction coil 230 surrounding the outside of the crucible 200. The inside of the crucible 200 may be heated when high-frequency current flows in the induction coil 230.

As shown in FIG. 6C, the silicon carbide raw material SIC_P is sublimated, and the single crystal silicon carbide SIC_C may thus be grown on a lower surface of the seed 210. After separating the seed holder 220 attached to the upper portion of the crucible 200 from the crucible 200, the single crystal silicon carbide SIC_C may thus be obtained.

Although the embodiments of the present invention are described, those with ordinary skill in the technical field to which the present invention pertains will understand that the present invention can be carried out in other specific forms without changing the technical idea or essential features. Therefore, the above-described embodiments are to be considered in all aspects as illustrative and not restrictive.

### DESCRIPTION OF THE SYMBOLS

100: reactor
110: fibrous carbon body
120: fiber bundle
130: graphite electrode
200: crucible
210: seed
220: seed holder
230: induction coil
240: reaction chamber
SIC_P1: first silicon carbide powder
SIC_P2: second silicon carbide powder
SIC_C: single crystal silicon carbide

1. A method for preparing silicon carbide powder, the method comprising:
providing a precursor gas onto a fibrous carbon body in a reactor to deposit silicon carbide (SiC) on the fibrous carbon body;
recovering the silicon carbide deposited on the fibrous carbon body to obtain a first silicon carbide powder; and
oxidizing the first silicon carbide powder,
wherein a molecule of the precursor gas include a silicon atom and a carbon atom.

2. The method of claim 1, wherein the precursor gas comprises methyltrichlorosilane (MTS).

3. The method of claim 1, wherein the temperature inside the reactor upon the depositing of silicon carbide is 1,400° C. to 1,600° C.

4. The method of claim 1, wherein the fibrous carbon body comprises graphite fibers.

5. The method of claim 1, wherein the fibrous carbon body comprises a fiber bundle protruding from a surface thereof.

6. The method of claim 5, wherein the silicon carbide is deposited in a form of droplets on one end of the fiber bundle.

7. The method of claim 1, wherein the first silicon carbide powder has an average particle size of 200 μm to 5 mm.

8. The method of claim 1, wherein the reactor comprises an electrode provided in an inside of the reactor to heat the inside,
silicon carbide is deposited on the electrode upon the depositing of the silicon carbide,
wherein the method for preparing silicon carbide powder further comprises:
recovering and grinding the silicon carbide deposited on the electrode to obtain a second silicon carbide powder, and
oxidizing the second silicon carbide powder.

9. The method of claim 8, wherein the second silicon carbide powder has an average particle size of 200 μm to 10 mm.

10. The method of claim 1, further comprising heat-treating the first silicon carbide powder at temperatures of 700° C. to 800° C.

11. A method for preparing single crystal silicon carbide, the method comprising:
providing a precursor gas onto a fibrous carbon body in a reactor to deposit silicon carbide on the fibrous carbon body;
recovering the silicon carbide deposited on the fibrous carbon body to obtain a first silicon carbide powder;
providing a silicon carbide raw material including the first silicon carbide powder into a crucible; and
sublimating the silicon carbide raw material to grow single crystal silicon carbide on a seed attached to an upper portion of the crucible.

12. The method of claim 11, wherein the sublimating of a silicon carbide raw material comprises heating at a temperature inside the crucible of 1,800° C. to 2,400° C.

13. The method of claim 11, wherein the reactor comprises an electrode provided in an inside of the reactor to heat the inside,
silicon carbide is deposited on the electrode upon the depositing of the silicon carbide,
wherein the method for preparing single crystal silicon carbide further comprises:
recovering and grinding the silicon carbide deposited on the electrode to obtain a second silicon carbide powder; and
mixing the second silicon carbide powder with the first silicon carbide powder to prepare the silicon carbide raw material.

14. The method of claim 11, further comprising oxidizing the first silicon carbide powder.
